(19) United States
(12) Patent Application Publication
(10) Pub. No.: US 2013/0048961 A1
(43) Pub. Date: Feb. 28, 2013

(54) ORGANIC LIGHT EMITTING DEVICE WITH ENHANCED EMISSION UNIFORMITY

(71) Applicants: Kamala Rajan, Newton, PA (US); Peter Levermore, Lambertville, NJ (US); Ruiqing Ma, Morristown, NJ (US)

(72) Inventors: Kamala Rajan, Newton, PA (US); Peter Levermore, Lambertville, NJ (US); Ruiqing Ma, Morristown, NJ (US)

(73) Assignee: Univeral Display Corporation, Ewing, NJ (US)

(21) Appl. No.: 13/576,668

(22) PCT Filed: Feb. 3, 2010
(86) PCT No.: PCT/US2010/023034

§ 371 Date: Oct. 18, 2012

(51) Int. Cl. H01L 51/52; H01L 51/56

(52) U.S. Cl. 257/40; 438/46; 257/E51.018; 257/E51.001

(57) ABSTRACT

A light emitting device with high light emission uniformity is disclosed. The device contains a first electrically conductive layer having a positive polarity and an electrically conductive uniformity enhancement layer in contact with the first electrically conductive layer. The device also contains a second electrically conductive layer having a negative polarity and a light-emitting structure situated between the first and the second electrically conductive layers. The light-emitting structure contains an organic material in direct contact with the second electrically conductive layer. The uniformity enhancement layer transmits essentially all wavelengths of light emitted by the light-emitting structure. Compared to devices lacking a uniformity enhancement layer, the device exhibits higher spatial uniformity in luminance and in color spectrum.

### FIELD OF INVENTION

The present application relates to organic light-emitting devices.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays; illumination, including lighting panels; and backlighting Several OLED materials and configurations are described in U.S. Pat. Nos. 5,844,363, 6,303,238, and 5,707,745, which are incorporated herein by reference in their entirety.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction.

More details on OLEDs, and the definitions described above, maybe found in U.S. Pat. No. 7,279,704, which is incorporated herein by reference in its entirety.

For some applications of OLEDs, such as elements of lighting panels, it may be desirable that the light emitted by the OLED be highly uniform in both intensity and in color spectrum across an emitting surface of the device. The larger the area of the emitting surface the more difficult it may be to achieve this desired uniformity. One cause of non-uniform emission may be variations in electrical potential across a face of a device from which light is emitted. Achieving a more uniform potential across the face may result in a greater uniformity of light emission across the face.

### SUMMARY

A light emitting device with high light emission uniformity is disclosed. The device is comprised of a first electrically conductive layer having a positive polarity and an electrically conductive uniformity enhancement layer in contact with the first electrically conductive layer. The device is further comprised of a second electrically conductive layer having a negative polarity and a light-emitting structure situated between the first and the second electrically conductive layers. The light-emitting structure is comprised of an organic material in direct contact with the second electrically conductive layer. The uniformity enhancement layer transmits essentially all wavelengths of light emitted by the light-emitting structure.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an embodiment of an organic light emitting device with an electrically conductive uniformity enhancement layer.

FIG. 4 shows a second embodiment of an organic light emitting device with an electrically conductive uniformity enhancement layer.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

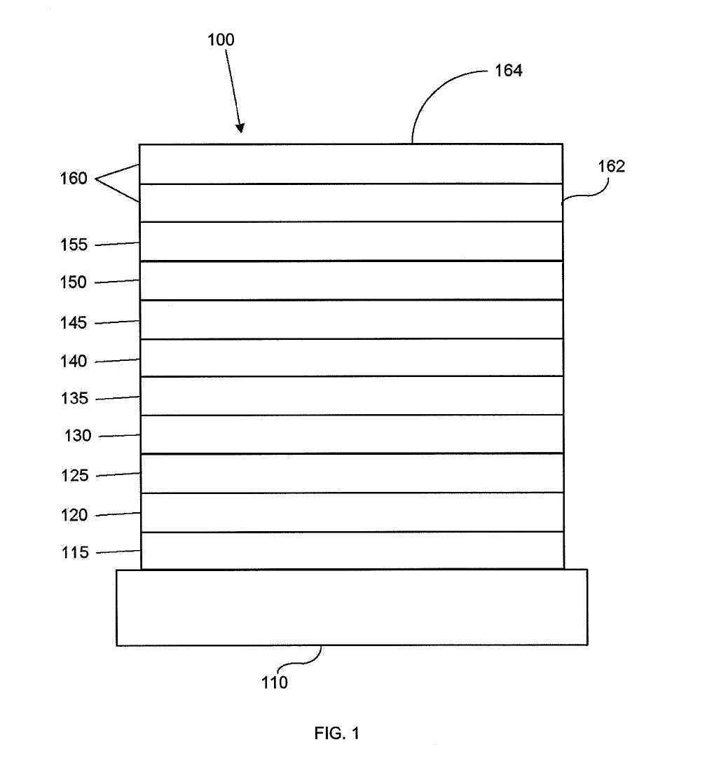

FIG. 1 shows an organic light emitting device 100. The figures are not necessarily drawn to scale. Device 100 may include a substrate 110, an anode 115, a hole injection layer (HIL) 120, a hole transport layer (HTL)125, an electron blocking layer (EBL)130, an emissive layer (EML) 135, a hole blocking layer (HBL)140, an electron transport layer (ETL) 145, an electron injection layer (EIL) 150, a protective layer 155, and a cathode 160. Cathode 160 may be a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference herein.

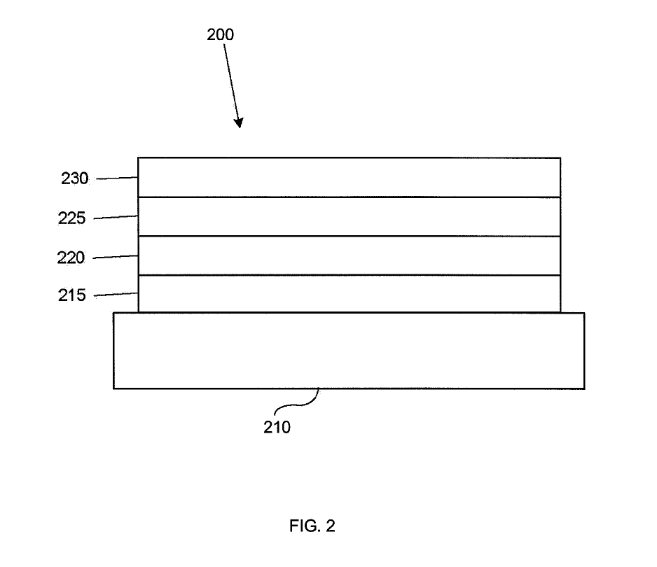

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. patent application Ser. No. 10/233,470, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

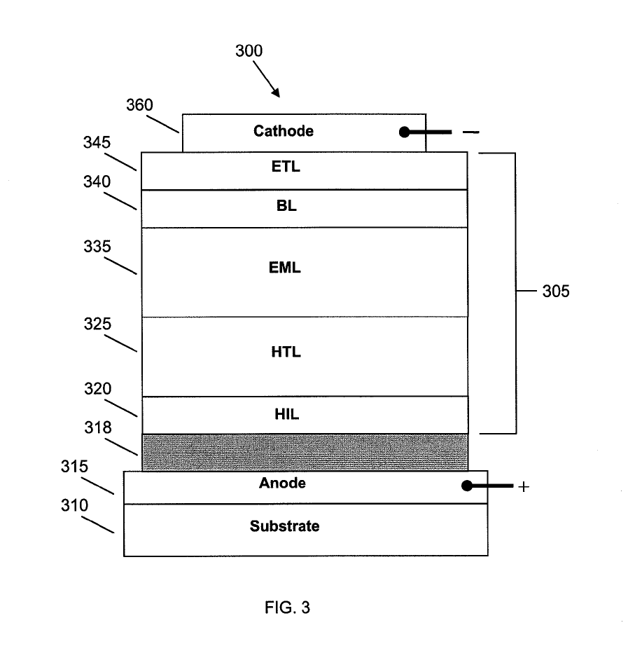

FIG. 3 shows an embodiment of an organic light emitting device (OLED) 300 with an electrically conductive uniformity enhancement layer 318. The OLED 300 contains layers built on a substrate 310, which may be transparent. (Throughout this description, “transparent” means transmitting at least 50% of incident light at wavelengths in the range 400-700 nm, generally understood as the visible spectrum.) Some of the layers correspond to those shown in FIGS. 1 and 2 in terms of functionality. Light may be emitted through the substrate 310, through an electrically conductive layer 360 opposite the substrate 310, or through both.

On the substrate 310 is a first electrically conductive layer 315. In the embodiment shown in FIG. 3, first electrically conductive layer 315 is configured as an anode, with a positive polarity relative to a second electrically conductive layer 360. The relative polarities are indicated in FIG. 3. The opposite polarity, in which layer 315 has a negative polarity relative to electrically conductive layer 360, may also be used with corresponding changes to layers 320, 325, 335, 340, and 345, which are described below. The first electrically conductive layer 315 may be a transparent conductive layer, such as a transparent conductive oxide; a transparent conductive polymer; a transparent conductive organic composite; a transparent semiconductor material; a transparent conductive film comprising carbon nanotubes; or a metal layer thin enough to be transparent.

In contact with the first electrically conductive layer 315 is an electrically conducting uniformity enhancement layer 318, described in detail below. As used herein, the terms “uniformity enhancement layer” and “enhancement layer” refer to an electrically conducting uniformity enhancement layer, such as feature 318 of FIG. 3 and equivalents. The term “uniformity enhancement” is used here to indicate that layer 318 acts to enhance the spatial uniformity of light emitted by the OLED 300. This includes both uniformity of overall intensity and uniformity of emitted color spectrum. It is believed that the uniformity may be enhanced by the uniformity enhancement layer 318 because the uniformity enhancement layer 318, being a relatively good electrical conductor, reduces a difference in electrical potential between the center and the outer edges of the OLED 300—that is, along a horizontal direction from center to edge in a device oriented as the embodiment in FIG. 3. Without enhancement layer 318, this potential difference may be greater because of a relatively higher resistance of the first electrically conductive layer 315. Higher resistance gives rise to a higher potential difference between the center and the outer edges due to Ohm's Law voltage drop (IR).

The OLED 300 further contains a light-emitting structure 305 comprised of at least one organic layer. The following details of the light emitting structure 305 are not intended to be limiting. In the OLED embodiment 300 of FIG. 3, light emitting structure 300 is comprised of a hole injection layer (HIL) 320, a hole transport layer (HTL) 325, an emitting layer (EML) 335, a blocking layer (BL) 340, and an electron transport layer (ETL) 345. Descriptions of these layer types may be found above and in the above mentioned patents incorporated herein by reference.

A second electrically conductive layer 360 may be in direct contact with an organic layer 345 of the light emitting structure 305. In the embodiment shown in FIG. 3, the second electrically conductive layer 360 is configured as a cathode, with negative polarity relative to the first electrically conductive layer 315. The second electrically conductive layer 360 may be transparent, semi-transparent or reflective. Layer 360 may be a transparent conductive layer, such as a transparent conductive oxide; a transparent conductive polymer; a transparent conductive organic composite; a transparent semiconductor material; a transparent conductive film comprising carbon nanotubes; or a metal layer thin enough to be transparent. The second electrically conductive layer 360 may comprise a reflective layer of aluminum or silver or any other metal or metal oxide. Layer 360 may be comprised of more than one layer of different materials.

In the embodiment shown in FIG. 3, the enhancement layer 318 is situated between the first electrically conductive layer 315, configured as an anode, and a first layer 320 of the light emitting structure 305. The enhancement layer 318 may contain a metal, a semiconductor, or an electrically conductive organic material, such as polymer or organic composite, singly or in any combination and in any order. Metals which may be used for enhancement layer 318 include calcium, magnesium, aluminum, gold or silver. The enhancement layer may be a thin film fabricated using such techniques as sputtering, spin coating, vacuum thermal evaporation, chemical vapor deposition or self-assembly. A specific example of an enhancement layer that has been investigated, described in greater detail below, is comprised of a film of calcium having a thickness equal to or less than about 5 nanometers.

The enhancement layer 318 does not function as a microcavity, either by itself or in combination with other layers. A microcavity is an optically resonant structure designed to increase the external emission intensity of a light emitting device in a particular direction. Because of its resonant nature, a microcavity may significantly alter the spectrum of the light emitted by the device. Evidence is presented below to show that, in an embodiment reduced to actual practice, enhancement layer 318 does not act as, or give rise to, a microcavity. A light-emitting device employing a microcavity is described in U.S. Published Patent Application No. US2008/0067921.

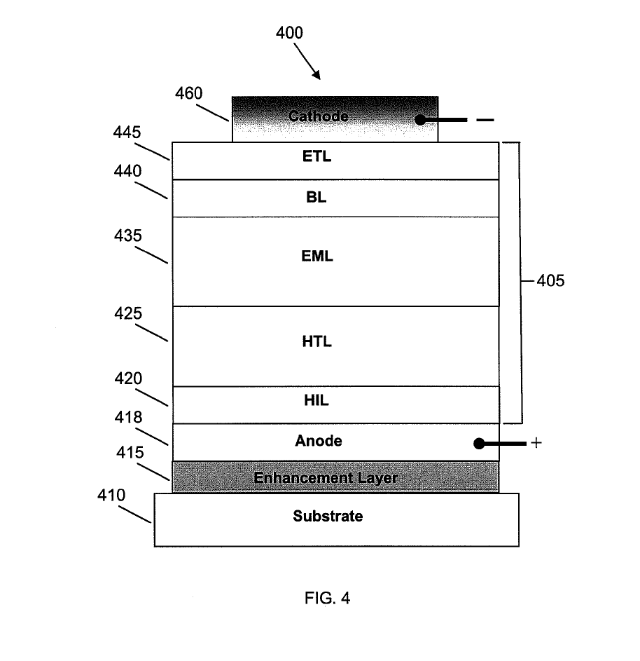

FIG. 4 shows a second embodiment of an OLED 400 having a uniformity enhancement layer 415. In this embodiment the uniformity enhancement layer 415 is situated between a substrate 410 and a first electrically conductive layer 418. Electrically conductive layer 418 may be configured to function as an anode, having a positive polarity relative to a second electrically conductive layer 460, which may be configured to function as a cathode. The reverse polarity, with layer 418 having a negative polarity with respect to layer 460, may also be used, with corresponding changes to layers 420, 425, 435, 440, and 445. These other layers in FIG. 4 correspond to layers in FIG. 3 and are numbered correspondingly.

In an alternative embodiment, a uniformity enhancement layer may be situated between two electrically conductive layers and in contact with both. A resulting sandwich-like structure may be configured as a composite anode.

Table 1 shows results of comparative measurements between two 5 cm.×5 cm. OLED panels emitting white light, one (Device B) having an enhancement layer as described above, the other (Device A) having the same layer structure as Device B but without an enhancement layer. Measurements were taken at a constant current density of 4 mA/cm².

TABLE 1

| | Luminance and 1931 CIE | | Luminance and 1931 CIE | |
|---|---|---|---|---|
| | (x, y) of Device A | | (x, y) of Device B | |
| Position | (at V = 8.00 V) | | (at V = 7.66 V) | |
| Center (X) | 921 cd/m² | (0.321, 0.361) | 919 cd/m² | (0.311, 0.361) |
| Average | 1245.0 | (0.321, 0.360) | 1024.8 | (0.312, 0.362) |
| Corner | | | | |
| Luminance | | | | |

| | | |
|---|---|---|
| Drop: Corner | 26.0% | 10.2% |
| to Center | | |

The enhancement layer in Device B is a 2 nanometer (nm) thick layer of calcium (Ca) situated as shown in FIG. 3. The presence of the enhancement layer reduces the drop in luminance from the corner to the center of the panel from 26.0% to 10.2%. In addition, the voltage required to deliver the same current density is 0.34 V lower for the Device B with the enhancement layer. This suggests that the resistivity of the anode has been reduced by the enhancement layer. Emission is significantly more uniform for the device with the enhancement layer. The data also show that emission color and luminance at the center of each pixel is not significantly affected by the enhancement layer. This demonstrates that the enhancement layer does not act as a microcavity. Additionally, the applied voltage required to deliver the same current density is lower for Device B, this demonstrates that the voltage drop across the anode is reduced by the enhancement layer. It also demonstrates that the enhancement layer does not introduce a significant barrier to charge injection. This demonstrates that the work function of the anode is not significantly affected, so the OLED does not compare to inverted structures where, for example, a thin metallic layer is used for electron injection.

In a similar investigation, two 5 cm.×5 cm. blue-light emitting devices are compared, one with an enhancement layer, the other one without, but otherwise having the same layer structure. With no enhancement layer, luminance in the center of the emitting face of the device is 91.2% of the average luminance at the edge. With a 2 nm thick Ca enhancement layer, luminance in the center is 98.1% of the average luminance at the edge. Thus, the luminance of the emitted light varies less than 2% over a distance of at least 2.5 centimeters across an emitting face of the device. It is expected that similar improvement in luminance uniformity will be achieved in devices of dimensions significantly larger than 5 cm.×5 cm. It may not be necessary, however, to maintain such a high level of uniformity across the lighting panel at higher luminance levels and/or for much larger panel sizes. For example, luminance of the emitted light that varies less than 10%, or even as much as 20%, over a distance of 2.5 centimeters across an emitting face of the device may be adequate. Such uniformity would also be readily achievable using the methods and structures disclosed here.

OLEDs fabricated in accordance with the above embodiments may be incorporated into a wide variety of consumer products, including flat panel displays, computer monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, or a sign. Various control mechanisms may be used to control OLEDs fabricated in accordance with the above embodiments, including passive matrix and active matrix. Many of the devices are intended for use in a temperature range comfortable to humans, such as 18° C. to 30° C., and more preferably at room temperature (20-25° C.).

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

It is understood that the various embodiments described herein are by way of example only, and are not intended to limit the scope of invention. For example, many of the materials and structures described herein may be substituted with other materials and structures without deviating from the spirit of the embodiments. The embodiments as claimed may therefore include variations from the particular examples and preferred embodiments described herein, as will be apparent to one of skill in the art. It is understood that various theories as to why various embodiments work are not intended to be limiting.

What is claimed is:

1. A light emitting device with high light emission uniformity, comprising:
a first electrically conductive layer having a positive polarity;
an electrically conductive uniformity enhancement layer in contact with the first electrically conductive layer;
a second electrically conductive layer having a negative polarity; and
a light-emitting structure situated between the first and the second electrically conductive layers, the light-emitting structure comprising an organic material in direct contact with the second electrically conductive layer;
wherein the uniformity enhancement layer transmits essentially all wavelengths of light emitted by the light-emitting structure.

2. The device of claim 1, wherein the uniformity enhancement layer is situated between the first electrically conductive layer and the light emitting structure.

3. The device of claim 1, wherein the uniformity enhancement layer is situated between the first electrically conductive layer and the substrate.

4. The device of claim 1, wherein the uniformity enhancement layer comprises at least one of a metal, a transparent conductive oxide, a semiconductor, or an electrically conductive organic material.

5. The device of claim 4, wherein the metal comprises at least one of calcium, aluminum, magnesium, gold, or silver.

6. The device of claim 1, wherein the uniformity enhancement layer comprises a film fabricated by at least one of: sputtering, spin coating, vacuum thermal evaporation, chemical vapor deposition, or self-assembly.

7. The device of claim 1, wherein the uniformity enhancement layer comprises calcium and has a thickness less than about 5 nanometers.

8. The device of claim 1, wherein at least one of the first or the second electrically conductive layers is transparent.

9. The device of claim 1, wherein at least one of the first or the second electrically conductive layers comprises a transparent conductive oxide.

10. The device of claim 1, wherein luminance of the emitted light varies less than 2% over any distance of at least 2.5 centimeters across an emitting face of the device.

11. A light emitting device with high light emission uniformity, comprising:
a substrate;
a first electrically conductive layer disposed over the substrate and having a positive polarity;
a light-emitting structure comprising an organic material disposed over the first electrically conductive layer;
a second electrically conductive layer disposed over the light-emitting structure and in direct contact with the organic material, the second electrically conductive layer having a negative polarity; and
an electrically conductive uniformity enhancement layer disposed between the substrate and the light-emitting structure, the uniformity enhancement layer transmitting essentially all wavelengths of light emitted by the light-emitting structure.

12. The device of claim 11, wherein the electrically conductive uniformity enhancement layer is disposed between the substrate and the first electrically conductive layer.

13. The device of claim 11, wherein the uniformity enhancement layer is disposed between the first electrically conductive layer and the light-emitting structure.

14. The device of claim 11, wherein the uniformity enhancement layer comprises at least one of a metal, transparent conductive oxide, a semiconductor, or an electrically conductive organic material.

15. The device of claim 14, wherein the metal comprises at least one of magnesium, calcium, aluminum, gold or silver.

16. The device of claim 11, wherein the uniformity enhancement layer comprises a film fabricated by at least one of: sputtering, spin coating, vacuum thermal evaporation, chemical vapor deposition or self-assembly film growth.

17. The device of claim 11, wherein the uniformity enhancement layer comprises calcium and has a thickness less than about 5 nanometers.

18. A method for forming a light emitting device with high light emission uniformity, comprising:
disposing a first electrically conductive layer formed over a substrate and having a positive polarity;
disposing a light-emitting structure comprising an organic material over the first electrically conductive layer;
disposing a second electrically conductive layer over the light-emitting structure and in direct contact with the organic material, the second electrically conductive layer having a negative polarity; and
disposing an electrically conductive uniformity enhancement layer between the substrate and the light-emitting structure, the uniformity enhancement layer transmitting essentially all wavelengths of light emitted by the light-emitting structure.

19. The method of claim 18, wherein the uniformity enhancement layer is disposed between the substrate and the first electrically conductive layer.

20. The method of claim 18, wherein the uniformity enhancement layer is disposed between the first electrically conductive layer and the light-emitting structure.
